(19) United States
(12) Patent Application Publication
(10) Pub. No.: US 2026/0112436 A1
(43) Pub. Date: Apr. 23, 2026

(54) DETECTING MEMORY READ ERRORS BY TRIGGERING MORE WORD LINE SCANS IF NEEDED

(71) Applicant: Micron Technology, Inc., Boise, ID (US)

(72) Inventors: Zhongyuan Lu, Boise, ID (US); Ugo Russo, Boise, ID (US); Juane Li, Milpitas, CA (US)

(73) Assignee: Micron Technology, Inc., Boise, ID (US)

(21) Appl. No.: 19/346,454

(22) Filed: Sep. 30, 2025

Related U.S. Application Data
(60) Provisional application No. 63/708,701, filed on Oct. 17, 2024.

(51) Int. Cl. G11C 29/02; G11C 16/26; G11C 29/52

(52) U.S. Cl. CPC G11C 29/022; G11C 16/26; G11C 29/52

(57) ABSTRACT

A method performed by a memory device to detect memory read errors is provided. The method comprises scanning a first memory cell associated with a first word line to obtain a first margin. The first word line is one of a list of word lines associated with target memory cells in a target memory block. The target memory cells are predetermined for scanning. The method further comprises determining if the first margin is lower than a triggering threshold, and in accordance with the determination, scanning a second memory cell associated with a second word line in the list of word lines associated with the target memory cells in the target memory block to obtain a second margin. The method further comprises marking the target memory block as bad upon determining that the second margin is lower than a folding threshold. The folding threshold is less than the triggering threshold.

### CROSS-REFERENCE TO RELATED APPLICATIONS

This application claims priority to U.S. Provisional Application No. 63/708,701, filed on Oct. 17, 2024, entitled “DETECTING MEMORY READ ERRORS BY TRIGGERING MORE WORD LINE SCANS IF NEEDED,” the contents of which is incorporated by reference in its entirety for all purposes.

### TECHNICAL FIELD

This disclosure relates to one or more systems for memory, including techniques for triggering more word line scans if needed.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory calls in a memory device, in accordance with examples as disclosed herein.

FIG. 3 is a block diagram of an example apparatus for implementing one or more systems and for performing one or more methods described herein, in accordance with examples as disclosed herein.

FIG. 4 illustrates voltage margin distributions of memory cells on three example word lines in a memory block when different memory read mechanisms are used to read the memory cells.

FIG. 5 is a flowchart illustrating a method for performing periodic scan on a target memory block that supports techniques for triggering more word line scans if needed in accordance with examples as disclosed herein.

FIG. 6 is a flowchart illustrating another method for performing periodic scan on a target memory block that supports techniques for triggering more word line scans if needed in accordance with examples as disclosed herein.

### DETAILED DESCRIPTION

NAND flash memory may be susceptible to the “read disturb” effect, which can gradually shift the threshold voltages of certain memory cells. This phenomenon may result in reduced voltage margins for the affected cells, thereby increasing the likelihood of memory read errors in a memory block. To mitigate or prevent such read errors, memory controllers may periodically scan cells associated with word lines that exhibit low voltage margins. However, the impact of read disturb is not uniform across all word lines in a memory block. Some word lines may exhibit a more significant reduction in voltage margin than others. The specific word lines affected by these declines can vary not only between different blocks but also within a single block.

There are several approaches available for a memory controller to conduct periodic scans of a memory block in order to detect whether the voltage margin of any target cell has reached a folding threshold, indicating that the memory block is at risk. One common approach involves the memory controller randomly selecting a word line from a predetermined list of word lines for each periodic scan. However, this approach has drawbacks, as random selection may fail to identify the “worst” word line with the lowest voltage margin, potentially leading to memory read errors.

To increase the likelihood of detecting the word line with the lowest voltage margin, more word lines can be scanned during each periodic scan. However, scanning additional word lines requires more time and may negatively impact system performance. The present disclosure describes a novel approach that enhances the detection of a potential “bad” memory block by dynamically adjusting the number of word lines scanned, thereby improving the reliability of memory operations without significantly compromising performance.

In one embodiment, the memory controller is configured to randomly select a word line from a predefined list of mandatory word lines. Upon selection, the memory controller scans the memory cells associated with the selected word line to determine the voltage margin at a logic level, e.g., at level L0. If the voltage margin is less than or equal to a predefined threshold, it indicates that the memory block may be at risk. To verify this, the memory controller scans more memory cells associated with the mandatory word lines to obtain the lowest voltage margin. If the lowest voltage margin is less than or equal to a predefined folding threshold, the memory block is deemed at risk, and will be marked as “bad” and reprogrammed. If, on the other hand, the lowest voltage margin is greater than the folding threshold, the memory block is deemed safe, allowing for further memory access operations on the memory block.

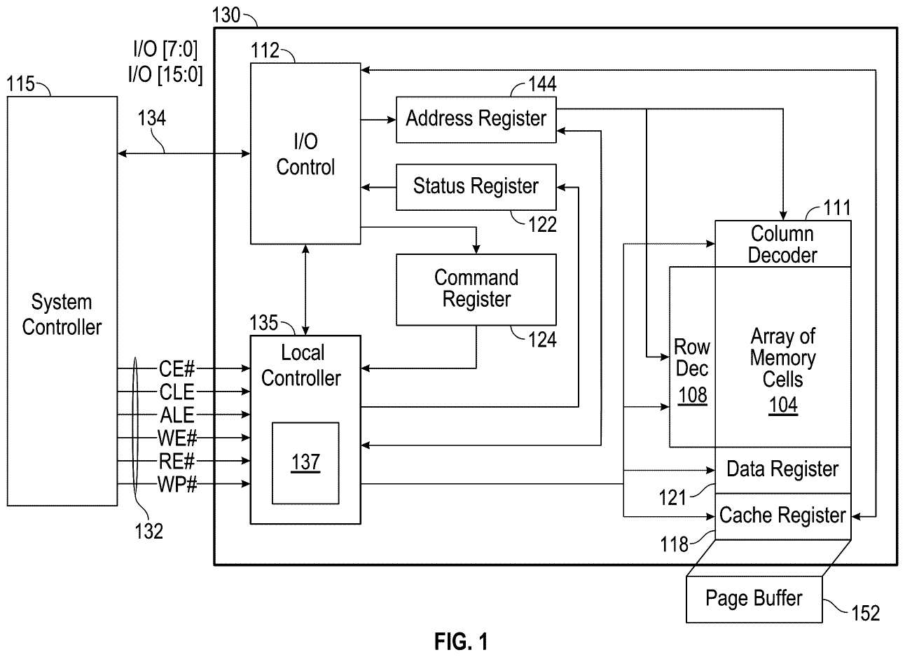

FIG. 1 is a simplified block diagram of a memory device 130 in communication with a system controller 115 of a memory system, according to an embodiment. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device. Device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. Row decode circuitry 108 and column decode circuitry 111 may simply be referred to as row decoder 108 and column decoder 111, respectively. A command register 124 is in communication with the I/O control circuitry 112 and local controller 135 to latch incoming commands.

A memory controller (e.g., the local controller 135 internal to memory device 130) controls access to the array of memory cells 104 in response to the commands and generates status information for the external system controller 115. For example, the local controller 135, on its own or in response to a command provided by external system controller 115, is configured to perform access operations (e.g., read operations, programming operations, and/or erase operations) on the array of memory cells 104. The local controller 135 is in communication with row decode circuitry 108 and column decode circuitry 111 to control the row decode circuitry 108 and column decode circuitry 111 according to the addresses.

In some embodiments, local controller 135 communicates with the external system controller 115, which may be a host controller (e.g., an UFS or eMMC controller, or a CPU communicating with local controller 135) located in a host system or a memory system controller located in a memory system. In some embodiments, local controller 135 is disposed on the same semiconductor die as the memory array (e.g., array 104), and a separate system controller 115 is disposed on a different die. In other examples, some portions of memory device 130 may be disposed on a first die and other portions of memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of device 130. Thus, the second die may include system controller 115, I/O control 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, a system controller 115 and a local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

Local controller 135 is also in communication with a cache register 118 and a data register 121. In some embodiments, one or more cache registers 118 can collectively form at least a part of a cache buffer. Cache register 118 latches or buffers data, either incoming or outgoing, as directed by local controller 135 to temporarily store data while the array of memory cells 104 is busy writing or reading, respectively, other data. During a program operation (e.g., write operation), data can be passed from cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to cache register 118. In some embodiments, cache register 118 and/or the data register 121 can form at least a portion of a page buffer 152 of the memory device 130. The page buffer 152 can further include sensing devices such as a sense amplifier, to sense a data state of a memory cell of the array of memory cells 104, e.g., by sensing a state of a data line connected to that memory cell. A status register 122 can be in communication with I/O control circuitry 112 and the local memory controller 135 to latch the status information for output to system controller 115.

As shown in FIG. 1, memory device 130 receives various control signals via local controller 135 from system controller 115 over a control link 132. For example, the control signals can include a chip enable signal CE#, a command latch enable signal CLE, an address latch enable signal ALE, a write enable signal WE#, a read enable signal RE#, and a write protect signal WP#. Additional or alternative control signals (not shown) can be further received over control link 132 depending upon the nature of memory device 130. In one embodiment, memory device 130 receives command signals (which represent commands), address signals (which represent addresses), and data signals (which represent data) from the system controller 115 over a multiplexed input/output (I/O) bus 134 and outputs data to the system controller 115 over I/O bus 134.

For example, the commands can be received over input/output (I/O) pins [7:0] of I/O bus 134 at I/O control circuitry 112 and can then be written into a command register 124. The addresses can be received over input/output (I/O) pins [7:0] of I/O bus 134 at I/O control circuitry 112 and can then be written into address register 144. The data can be received over input/output (I/O) pins [7:0] for an 8-bit device or input/output (I/O) pins [15:0] for a 16-bit device at I/O control circuitry 112 and then can be written into cache register 118. The data can be subsequently written into data register 121 for programming the array of memory cells 104.

In an embodiment, cache register 118 can be omitted, and the data can be written directly into data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description using 16 bits I/O bus 134 as an example, it is understood that bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

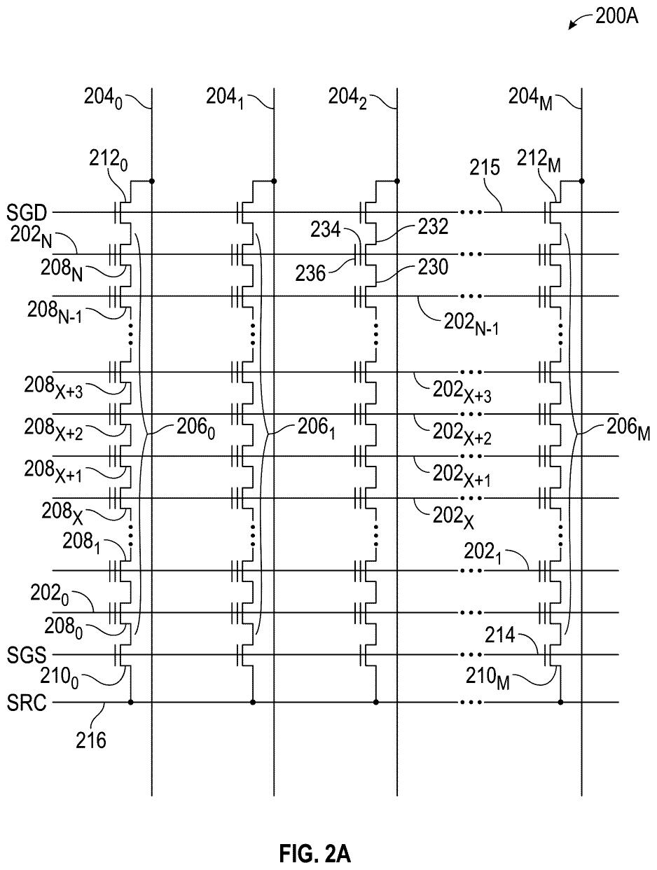

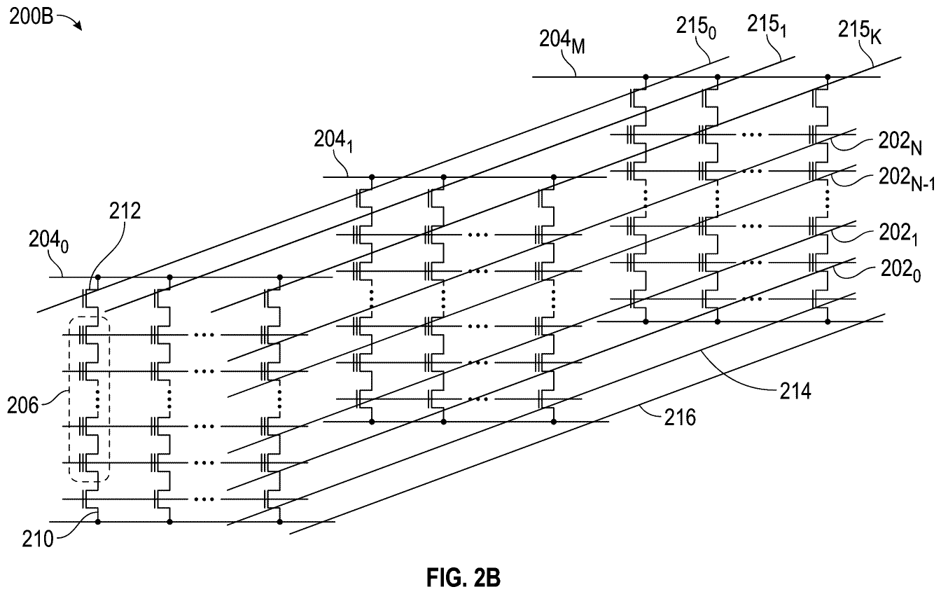

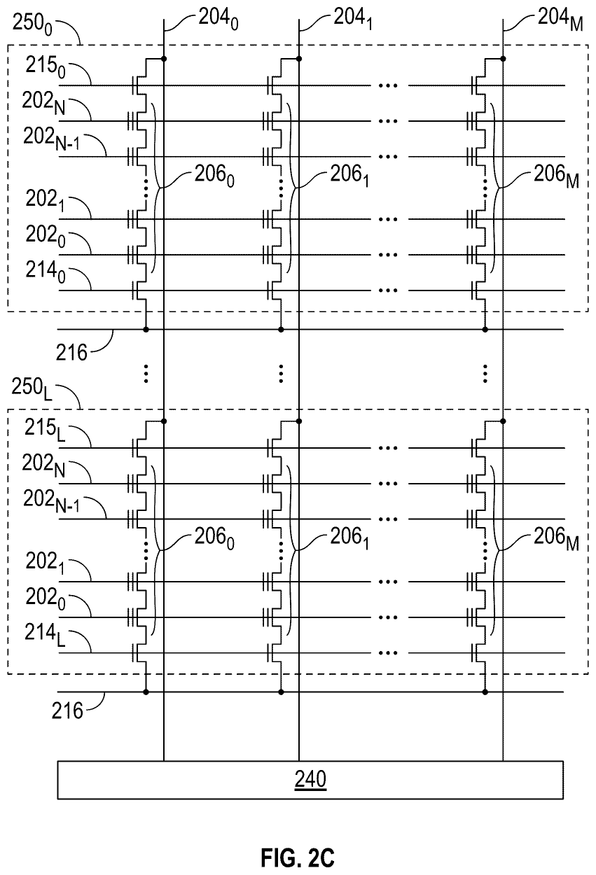

FIG. 2A-2B are example schematics of portions of an array of memory cells 200A, such as a NAND memory array. Array of memory cells 200A may be an example of memory array 104 of a memory device 130 as described with reference to FIG. 1 according to an embodiment. Memory array 200A includes access lines, such as word lines 202₀ to 202_{N}, and data lines, such as bit lines 204₀ to 204_{M}. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 204₀ for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, NAND strings 206 and bit lines 204 extend in substantially parallel planes. Alternatively, the memory array 200A in FIG. 2A can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. Memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bit lines 204₁, 204₃, 204₅, etc.) can be another physical page of the memory cells 208 (e.g., odd memory cells).

Although bit lines 204₃-204₅ are not explicitly depicted in FIG. 2A, it is apparent from the figure that the bit lines 204 of the array of memory cells 200A can be numbered consecutively from bit line 204₀ to bit line 204_{M}. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single programming operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 204₀-204_{M} by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 215₀-215_{K} to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 250₀-250_{L}. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 215₀. The common source 216 for the block of memory cells 250₀ can be a same source as the source 216 for the block of memory cells 250_{L}. For example, each block of memory cells 250₀-250_{L} can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 250₀-250_{L}.

The bit lines 204₀-204_{M} can be connected (e.g., selectively connected) to a buffer portion 240, which can be a portion of the page buffer 152 of the memory device 130. The buffer portion 240 can correspond to a memory plane (e.g., the set of blocks of memory cells 250₀-250_{L}). The buffer portion 240 can include sense circuits (which can include sense amplifiers) for sensing data values indicated on respective bit lines 204. In one example, buffer portion 240 can be a part of page buffer 152. As described below, multiple buffer portions 240 may collectively form a page buffer 152.

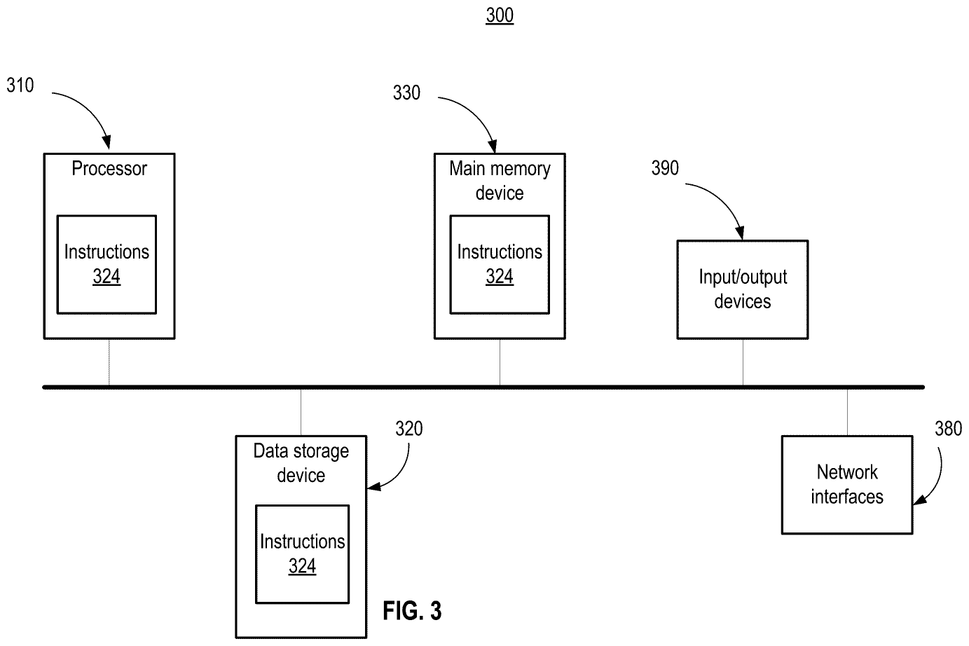

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

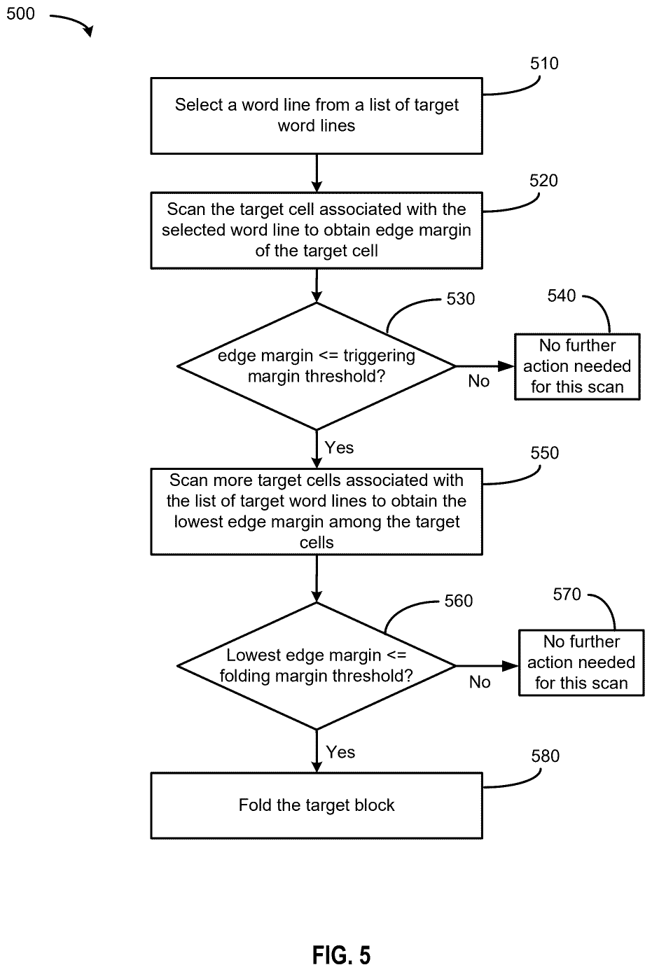

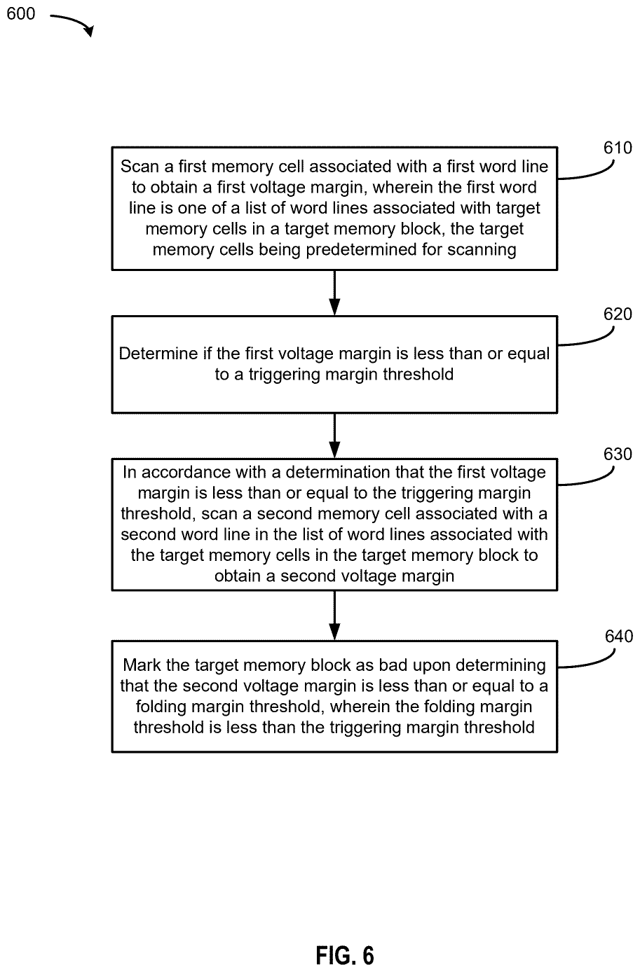

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 5-6, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 comprises a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 5-6 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 5-6. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may comprise one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each comprise a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

The phenomenon of “read disturb” in NAND flash memory may occur when the process of reading data from a selected cell inadvertently alters the threshold voltages of other memory cells within the same block. Read disturb can arise from multiple factors. During a read operation, the memory controller applies a read reference voltage (Vref) to the selected word line, which is coupled to the selected cell. To enable a fully conducting string, the memory controller also applies a pass-through voltage (Vpass) to all the unselected word lines, which are coupled to the cells on the same string that are not being read (the “unselected cells”). Although Vpass is lower than the programming voltage (Vpgm), it can still induce a “soft programming” effect on some or all the unselected cells. This effect can lead to gradual shifts in the threshold voltages of these unselected cells, particularly when the effect is accumulated over time.

Over time, these gradual shifts in threshold voltages may reduce voltage margins of the affected cells. However, the extent of reduction in voltage margins is not uniform across cells on all word lines. Cells on some word lines may suffer a more significant decline in voltage margin compared to cells on other word lines. The specific word lines affected by voltage margin declines can vary from block to block, or within a block. This variation can be attributed to several factors. One factor is process limitations, such as the non-uniformity of manufacturing processes and variations across different areas or dice of a memory wafer. For example, the distribution of voltage margins across word lines may differ between zones within the same memory wafer. Another factor is the use of different memory read mechanisms.

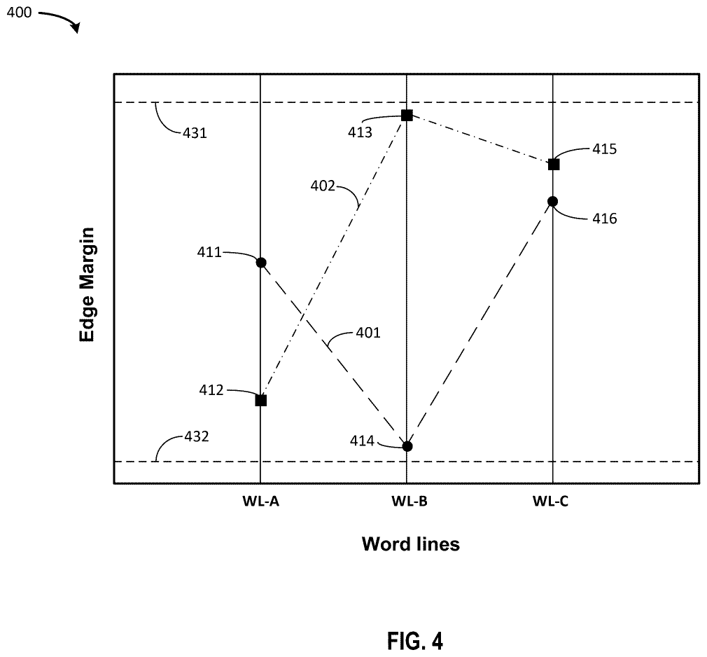

FIG. 4 illustrates voltage margin distributions of memory cells on three example word lines in a memory block when different memory read mechanisms are used to read the memory cells. The horizontal axis represents three example word lines of the memory block, i.e., word lines WL-A, WL-B, and WL-C. The vertical axis represents edge margins of the memory cells on the three word lines. Edge margin is the voltage margin of a logical level (e.g., L0, L1, etc.) for the corresponding cells on a word line. The vertical axis may also refer to as the “captured edge margin”.

In one embodiment, edge margin refers to the voltage difference between the read reference voltage (Vref) and the threshold voltage (Vth) of the level being read. Therefore, edge margin is defined as Vref-Vth. In another embodiment, edge margin refers to the voltage difference between different logical states of a cell, such as voltage margin between the two lowest states, L0 and L1, or voltage margin between two other states. Compared to the voltage margins of other logical states (L1, L2, etc.), the voltage margin of the lowest state, L0, may decline the most under read disturb effects. One reason for this is that cells in the L0 state have the lowest threshold voltage, resulting in a larger voltage differential relative to the pass voltage (Vpass), which leads to a more significant shift in the threshold voltage.

Graph 400 shows two different voltage margin trends when two different memory read mechanisms are used. Plot 401, which includes points 411, 414, and 416, shows voltage margin trend when partial block read mechanism is used to read the memory block. Plot 402, which includes points 412, 413, and 415, shows voltage margin trend when full block read mechanism is used to read the memory block. The three example word lines, WL-A, WL-B, and WL-C, represent the word lines in the memory block where the cells suffer significant low edge margins under both mechanisms.

In partial block read mechanism, the memory controller first programs memory cells associated with some word lines in a block. Cells associated with those word lines are being programmed first, while cells associated other word lines are not being programmed. When the memory controller reads from the programmed cells, it also applies a Vpass voltage to the other unprogrammed cells. Therefore, read disturb may also cause those unprogrammed cells to exhibit low voltage margins. As indicated in plot 401, cells suffer the lowest margin (point 414) at word line WL-B.

In full block read mechanism, the memory controller first programs memory cells on all the word lines in a block. Subsequently, the memory controller reads data from the cells in the block, which may induce a read disturb effect on those cells. Due to factors such as process limitations, memory cells on certain word lines may exhibit lower voltage margins than others. As indicated in plot 402, cells suffer the lowest margins (point 412) at word line WL-A.

FIG. 4 demonstrates that within a single block, edge margin distribution among the same word lines may vary depending on the read mechanisms used. Although the set of word lines in the block that suffer significant low margins may be the same under both mechanism, such as WL-A, WL-B, and WL-C in this example, the specific word line exhibiting the lowest margins can differ based on the different read mechanisms performed on the block (in this example, WL-B for partial block read mechanism and WL-A for full block read mechanism).

To prevent or reduce read errors in a memory block caused by read disturb, the memory controller can periodically scan cells associated with word lines exhibiting low voltage margins (the “target cells”). During these scans, the memory controller can perform read operations to detect the Raw Bit Error Rate (RBER) and/or the voltage margins of the target cells. The objective of the periodic scans is to timely detect if the voltage margin of any target cell has reached or fallen below a folding threshold represented by line 432 (also referred to as the “folding margin threshold”). The folding threshold could be 0 mV, or any other values. In FIG. 4, under both read mechanisms, no word lines are associated with edge margin at or below line 432. If the edge margin of at least one word line is less than or equal to the folding threshold 432, it indicates that the memory block is at risk, and the entire block needs to be “folded”. To fold a memory block, the memory controller may mark the block as “bad”, copy the valid data in the block to a new location, erase the block, and reprogram it.

There are several approaches for the memory controller to run periodic scans of a memory block to timely detect if the margin of any of the target cells has reached the folding threshold. The target cells are predetermined according to cell understanding such as cell metrics. There can be 3, 8, or any other number of target cells in a block. Word lines associated with these target cells are sometimes referred to as “target word lines” or “mandatory word lines”. The first approach is that the memory controller may scan all the target word lines during each periodic scan. However, scanning all target word lines each time can degrade system performance due to the time required for each scan.

The second approach is that the memory controller may randomly select one or more word lines from the target word lines for each periodic scan. This approach, however, carries a risk. Random selection may not always catch the “worst” target word line exhibiting the lowest margin among all the target word lines. If the margin of the “worst” target word line falls below the folding threshold and is not scanned, the memory controller would not flag the block as “bad”, and memory read/write operations would continue on the block. This could lead to memory read errors. For example, referring still to FIG. 4, assume partial read mechanism (plot 401) is used and that WL-A, WL-B, and WL-C are the target word lines associated with the three predetermined target cells. Further assume that the edge margin for WL-B (point 414) has reached below the folding threshold 432. This indicates that this memory block needs to be folded by the memory controller. However, if the memory controller randomly selects WL-A and/or WL-C, but not WL-B, for the scan, the reaching of the folding threshold cannot be detected because the edge margins for WL-A (point 411) and WL-C (point 416) are above the folding threshold. Consequently, under the second approach, a memory read error may not be timely prevented.

To address the above issues, a third approach is disclosed herein to timely detect potential “bad” blocks while maintaining optimal system performance by scanning more word lines as needed.

FIG. 5 is a flowchart illustrating method 500 for performing periodic scan on a target memory block that supports techniques for triggering more word line scans if needed in accordance with examples as disclosed herein. Method 500 may be performed by a memory device, or memory controllers in a memory device, such as host system controller, a system controller 115, and/or a local controller 135. In some embodiments, method 500 can be implemented in the form of firmware that is stored in computer readable medium and executed by local controller 135 to cause the memory device 130 to perform the operations described herein. In some embodiments, method 500 is performed by the memory controller during a read disturb detection operation on the target memory block, or a media scan operation on the target memory block.

At block 510, the memory controller selects a word line from a list of target word lines (also referred to as the “list of mandatory word lines” or “mandatory list”). In one embodiment, the mandatory list is predetermined according to cell understanding such as cell metrics. In other embodiments, the mandatory list is determined by the memory controller at runtime. In some embodiments, the mandatory list is determined based on the differences in voltage margins among the memory cells within the target memory block. For example, the mandatory list may include word lines associated cells that exhibit lower voltage margins relative to other cells in the memory block. In the example illustrated in FIG. 4, the discussion below assumes that partial read mechanism (plot 401) is used and that the mandatory list comprises three mandatory word lines, namely, WL-A, WL-B, and WL-C.

In one embodiment, the memory controller randomly selects a word line from the mandatory list. In another embodiment, the first word line to be scanned is randomly selected from the entire mandatory list, with subsequent word lines being randomly selected from the remaining word lines in the list until all have been scanned. After all word lines in the mandatory list have been scanned, the process repeats by randomly selecting from the entire mandatory list again. In other embodiments, the word line is selected sequentially or according to a predetermined pattern. For example, word lines at odd positions in the mandatory list may be selected first, followed by word lines at even positions in the mandatory list. Referring again to FIG. 4, for illustration, the memory controller may initially select WL-A from the mandatory list during one periodic scan.

At block 520, the memory controller scans the target cell associated with the word line selected in block 510 to obtain edge margin of the cell. During this scan, the memory controller performs read operations to ascertain the voltage margin of a logic level (e.g., L0) of the target cell. As previously explained, in one embodiment, edge margin represents the difference between the read reference voltage (Vref) and the threshold voltage (Vth) of L0 in the target cell. In some embodiments, the memory controller may ascertain the voltage margins of other states (e.g., L1, L2, etc.) of a memory cell.

At block 530, the value of edge margin is compared to a triggering margin threshold. The triggering margin threshold is set higher than the folding threshold of a memory block. As illustrated in FIG. 4, the triggering margin threshold 431 is set higher than the folding threshold 432. For example, the triggering margin threshold could be set at around 150 mV, or at any other value. If edge margin exceeds the triggering margin threshold, the process proceeds to block 540, where no further scanning action is needed for the current periodic scan, and the memory controller awaits the next periodic scan to restart the process at block 510. If, on the other hand, edge margin is less than or equal to the triggering margin threshold, this indicates that more scanning is needed, and the process proceeds to block 550 to scan more target cells. In the example illustrated in FIG. 4, since edge margin of the target cell associated with WL-A (point 411) is less than the triggering margin threshold 431, the process proceeds to block 550.

At block 550, the memory controller scans more target cells associated with the list of target word lines to obtain the lowest edge margin among the target cells. In the example illustrated in FIG. 4, the memory controller scans the target cells associated with the remaining word lines in the mandatory list, namely, WL-B and WL-C. In some embodiments, the memory controller may scan a subset of the target cells associated with the mandatory list. For example, the memory controller may scan only the target cell associated with WL-B, but not WL-C. In some embodiments, the memory controller may also scan one or more cells not associated with any word lines in the mandatory list.

After completing the scans, in one embodiment, the memory controller compiles a set of edge margins from all the scanned cells and identifies the cell with the lowest edge margin. In the example illustrated in FIG. 4, the target cell associated with WL-B exhibits the lowest edge margin (point 414). In another embodiment, rather than compiling a set of edge margins, the memory controller scans each cell individually and obtains its edge margin sequentially. Each time, the edge margin is compared to the folding threshold. If the Edge margin is less than or equal to the folding threshold, the memory controller marks the memory block as “bad” and initiates the folding process. If the edge margin exceeds the folding threshold, the memory controller proceeds to the next cell and repeats the scanning and comparison process. This continues until all cells associated with the word lines in the mandatory list have been scanned and compared. If no scanned cells have an edge margin lower than the folding threshold, no further action is required for the current scan, and the memory controller awaits the next periodic scan to initiate a new scanning process starting from block 510. In one embodiment, upon determining that no scanned cells have an Edge margin lower than the folding threshold, the memory controller may add the memory block in a wait list to enable more frequent scanning of the memory block. The memory controller may also identify more word lines to be included in mandatory list to be scanned later.

At block 560, the lowest edge margin is compared to the folding margin threshold. If the lowest edge margin is greater than the folding threshold, this indicates a less likelihood of memory block failure, and the process proceeds to block 570, where no further scanning action is needed for the current periodic scan. The memory controller awaits the next periodic scan to restart a new scanning process from block 510. In the example illustrated in FIG. 4, the lowest edge margin (point 414) is slightly above the folding threshold 432. Therefore, the process proceeds to block 570 and no further action is taken in this scan.

If, however, the memory controller determines at block 550 that the lowest edge margin is less than or equal to the folding threshold, this suggests that the memory block is at risk, and the entire block needs to be folded. At block 580, the memory controller folds the memory block. The memory controller may mark the block as “bad”, copy the valid data in the block to a new location, erase the block, and reprogram it.

In one embodiment, the triggering margin threshold is predetermined based on cell understanding. In other embodiments, triggering margin threshold may be determined by the memory controller at runtime. In one embodiment, the triggering margin threshold is set approximately at the mean value of the edge margins of all the target cells associated with the mandatory list. A more conservative approach involves setting the triggering margin threshold at a higher level. However, if the triggering margin threshold is set too high, it may trigger more frequent additional scans (blocks 550), resulting in unnecessary degradation of system performance. On the contrary, if the triggering margin threshold is set too low, e.g., too close to the folding threshold, it may trigger the additional scans less frequently, thereby increasing the risk of a potential undetected “bad” word line causing memory read failure. Ideally, the triggering margin threshold should be set at a level that provides enough “buffer zone”, such that if the first selected word line in block 510 is not the “worst” word line in the mandatory list, additional scans (block 550) can be triggered to detect that worst word line if its Edge margin falls below the folding threshold.

FIG. 6 is a flowchart illustrating method 600 for performing periodic scan on a target memory block that supports techniques for triggering more word line scans if needed in accordance with examples as disclosed herein. Method 600 may be performed by a memory device, or memory controllers in a memory device, such as host system controller, a system controller 115, and/or a local controller 135. In some embodiments, method 600 can be implemented in the form of firmware that is stored in computer readable medium and executed by local controller 135 to cause the memory device 130 to perform the operations described herein. In some embodiments, method 600 is performed by the memory controller during a read disturb detection operation on the target memory block, or a media scan operation on the target memory block.

At block 610, the memory controller scans a first memory cell associated with a first word line to obtain a first voltage margin, wherein the first word line is one of a list of word lines associated with target memory cells in a target memory block, the target memory cells being predetermined for scanning. The list of word lines associated with target memory cells are also referred to as the “mandatory list”. As previously explained, in one embodiment, the mandatory list is predetermined. Therefore, the associated target memory cells are also predetermined for scanning during a periodic scan of a target memory block. The first word line could be randomly selected from the mandatory list or selected according to a predetermined pattern. The memory controller scans the first memory cell associated with the first word line to obtain a first voltage margin of the cell.

At block 620, the memory controller determines if the first voltage margin is less than or equal to a triggering margin threshold. If the first voltage margin of the first memory cell is less than or equal to the triggering margin threshold, this indicates that more scanning is needed.

At block 630, in accordance with a determination that the first voltage margin is less than or equal to the triggering margin threshold, the memory controller scans a second memory cell associated with a second word line in the list of word lines associated with the target memory cells in the target memory block to obtain a second voltage margin. The second word line is selected from the mandatory list, and the associated second memory cell is scanned by the memory controller to obtain a second voltage margin.

At block 640, the memory controller marks the target memory block as bad upon determining that the second voltage margin is less than or equal to a folding margin threshold, wherein the folding margin threshold is less than the triggering margin threshold. The memory controller determines if the second voltage margin is less than or equal to a folding margin threshold. If this condition is met, the memory controller folds the target memory block by marking it as “bad”. The memory controller may also copy the valid data in the block to a new location, erase the block, and reprogram it.

As previously explained, in one embodiment, the triggering margin threshold is predetermined and is set higher than the folding threshold of a memory block. The triggering margin threshold may be set at a level that provides enough “buffer zone”, such that if the first word line is not the “worst” word line in the mandatory list, additional scan on the second word line in the mandatory list can be triggered to detect if the voltage margin of the second memory cell is lower than the folding threshold.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor (e.g., processor 310 of FIG. 3), the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
an array of memory cells comprising a plurality of memory cells; and
a memory controller configured to perform:
scanning a first memory cell associated with a first word line to obtain a first voltage margin, wherein the first word line is one of a list of word lines associated with target memory cells in a target memory block, the target memory cells being predetermined for scanning;
determining if the first voltage margin is less than or equal to a triggering margin threshold;
in accordance with a determination that the first voltage margin is less than or equal to the triggering margin threshold, scanning a second memory cell associated with a second word line in the list of word lines associated with the target memory cells in the target memory block to obtain a second voltage margin; and
marking the target memory block as bad upon determining that the second voltage margin is less than or equal to a folding margin threshold, wherein the folding margin threshold is less than the triggering margin threshold.

2. The memory device of claim 1, wherein the first voltage margin and the second voltage margin are margins between a voltage distribution associated with a first voltage level and a voltage distribution associated with a second voltage level of the associated memory cells, the first and second voltage levels being the lowest voltage levels of the associated memory cells.

3. The memory device of claim 1, wherein the memory controller is further configured to perform:
upon determining that the second voltage margin is greater than the folding margin threshold, scanning memory cells associated with remaining word lines in the list of word lines associated with the target memory cells in the target memory block to obtain remaining voltage margins;
determining whether any of the remaining voltage margins is less than or equal to the folding margin threshold; and
marking the target memory block as bad upon determining that any of the remaining voltage margins is less than or equal to the folding margin threshold.

4. The memory device of claim 3, wherein the memory controller is further configured to perform:
upon determining that none of the remaining voltage margins is less than or equal to the folding margin threshold, performing at least one of:
flagging the target memory block to enable more frequent scanning of the memory cells in the target memory block; or
identifying more word lines to be included in the list of word lines associated with the target memory cells in the target memory block.

5. The memory device of claim 3, wherein the remaining voltage margins are margins between a voltage distribution associated with a first voltage level and a voltage distribution associated with a second voltage level of the associated memory cells.

6. The memory device of claim 1, wherein the scanning of the first and second memory cells is performed by the memory controller during a read disturb detection operation on the target memory block, or a media scan operation on the target memory block.

7. The memory device of claim 1, wherein the memory controller is further configured to perform: randomly selecting the first word line from the list of word lines associated with the target memory cells in the target memory block.

8. The memory device of claim 1, wherein target memory cells in the target memory block are predetermined for scanning based on differences between voltage margins associated with the target memory cells and voltage margines associated with other memory cells in the target memory block.

9. A method performed by a memory device, the memory device comprising a memory array comprising a plurality of memory cells and a memory controller, the method comprising:
scanning a first memory cell associated with a first word line to obtain a first voltage margin, wherein the first word line is one of a list of word lines associated with target memory cells in a target memory block, the target memory cells being predetermined for scanning;
determining if the first voltage margin is less than or equal to a triggering margin threshold;
in accordance with a determination that the first voltage margin is less than or equal to the triggering margin threshold, scanning a second memory cell associated with a second word line in the list of word lines associated with the target memory cells in the target memory block to obtain a second voltage margin; and
marking the target memory block as bad upon determining that the second voltage margin is less than or equal to a folding margin threshold, wherein the folding margin threshold is less than the triggering margin threshold.

10. The method of claim 9, wherein the first voltage margin and the second voltage margin are margins between a voltage distribution associated with a first voltage level and a voltage distribution associated with a second voltage level of the associated memory cells, the first and second voltage levels being the lowest voltage levels of the associated memory cells.

11. The method of claim 9, further comprising:
upon determining that the second voltage margin is greater than the folding margin threshold, scanning memory cells associated with remaining word lines in the list of word lines associated with the target memory cells in the target memory block to obtain remaining voltage margins;
determining whether any of the remaining voltage margins is less than or equal to the folding margin threshold; and
marking the target memory block as bad upon determining that any of the remaining voltage margins is less than or equal to the folding margin threshold.

12. The method of claim 11, further comprising:
upon determining that none of the remaining voltage margins is less than or equal to the folding margin threshold, performing at least one of:
flagging the target memory block to enable more frequent scanning of the memory cells in the target memory block; or
identifying more word lines to be included in the list of word lines associated with the target memory cells in the target memory block.

13. The method of claim 11, wherein the remaining voltage margins are margins between a voltage distribution associated with a first voltage level and a voltage distribution associated with a second voltage level of the associated memory cells.

14. The method of claim 9, wherein the scanning of the first and second memory cells is performed by the memory controller during a read disturb detection operation on the target memory block, or a media scan operation on the target memory block.

15. The method of claim 9, further comprising: randomly selecting the first word line from the list of word lines associated with the target memory cells in the target memory block.

16. The method of claim 9, wherein target memory cells in the target memory block are predetermined for scanning based on differences between voltage margins associated with the target memory cells and voltage margines associated with other memory cells in the target memory block.

17. A memory device comprising:
an input/output (I/O) circuit;
an array of memory cells comprising a plurality of memory cells; and
a memory controller configured to perform:
scanning a first memory cell associated with a first word line to obtain a first voltage margin, wherein the first word line is one of a list of word lines associated with target memory cells in a target memory block, the target memory cells being predetermined for scanning;
determining if the first voltage margin is less than or equal to a triggering margin threshold;
in accordance with a determination that the first voltage margin is less than or equal to the triggering margin threshold, scanning a second memory cell associated with a second word line in the list of word lines associated with the target memory cells in the target memory block to obtain a second voltage margin; and
marking the target memory block as bad upon determining that the second voltage margin is less than or equal to a folding margin threshold, wherein the folding margin threshold is less than the triggering margin threshold.

18. A system comprising:
a processor;
a first memory controller; and
an array of memory cells comprising a plurality of memory cells; and
a memory controller configured to perform:
scanning a first memory cell associated with a first word line to obtain a first voltage margin, wherein the first word line is one of a list of word lines associated with target memory cells in a target memory block, the target memory cells being predetermined for scanning;
determining if the first voltage margin is less than or equal to a triggering margin threshold;
in accordance with a determination that the first voltage margin is less than or equal to the triggering margin threshold, scanning a second memory cell associated with a second word line in the list of word lines associated with the target memory cells in the target memory block to obtain a second voltage margin; and
marking the target memory block as bad upon determining that the second voltage margin is less than or equal to a folding margin threshold, wherein the folding margin threshold is less than the triggering margin threshold.
